(19) United States
(12) Patent Application Publication
(10) Pub. No.: US 2004/0094826 A1
(43) Pub. Date: May 20, 2004

(54) Leadframe pakaging apparatus and packaging method thereof

(76) Inventors: Chin An Yang, Hsin Tien City (TW); Hsueh Kuo Liao, Hsin Tien City (TW)

Correspondence Address: BIRCH STEWART KOLASCH & BIRCH, PO BOX 747, FALLS CHURCH, VA, 22040-0747, US

(21) Appl. No.: 10/611,875

(22) Filed: Jul. 3, 2003

(30) Foreign Application Priority Data
Sep. 20, 2002 (TW) 91121668

(51) Int. Cl. H01L 47/00

(52) U.S. Cl. 257/666

(57) ABSTRACT

A leadframe packaging apparatus including a die, at least two separated die pads each connected to a corresponding voltage level thereof, a plurality of leadfingers, and at least one passive component having two ends each connected to one of the two separated die pads. A packaging method for the leadframe apparatus is further provided, wherein the method prepares at least one die pad disposed in separated fashion, integrated circuit dies adhered to separated die pads, and passive components having two ends connected with separated die pads before forming the molding compound, thereby placing the passive components within the molding compound.

### BACKGROUND OF THE INVENTION

1. Field of the Invention

The present invention relates to a leadframe packaging apparatus and a packaging method thereof, and more particularly, to a leadframe apparatus of having a passive component placed between two separated die pads or two leadfingers within the molding compound of the apparatus and a packaging method thereof.

2. Description of the Prior Art

Please refer to FIG. 1 of a side view of a conventional art leadframe packaging apparatus 10 connecting with a printed circuit board 12. The printed circuit board 12 includes a top surface 13 and a bottom surface 14, each of which is selected from a group consisting of a power source layer, a ground layer, a signal layer, or a component layer from a viewpoint of 4-layer printed circuit board. Passive components 15 and 25 are disposed on the top surface 13 or the bottom surface 14 through the surface mount technology. For example, passive components 15 or 25 will be a de-coupling capacitor for reducing the mal-coupling in the circuitry or the noise between the high-frequency power source layer and the ground layer. In FIG. 1, it is apparent these passive components 15 and 25 are not disposed within the packaging apparatus 10, occupying some area of the top surface 13 or the bottom surface 14. Consequently, surfaces of the printed circuit board 12 are less likely to have some extra traces or the setting of other components if the amount of these passive components is large, leading to the annoying effect in the circuit layout while miniature printed circuit board is required. Further, these independently disposed de-coupling capacitors, located outside of the packaging apparatus 10, are not able to attenuate the switching noises between the high-frequency power source layer and the ground layer.

### SUMMARY OF THE PRESENT INVENTION

It is therefore a primary object of the present invention to provide a leadframe packaging apparatus having passive components therein and a method thereof. Placing passive components within the molding compound of the packaging apparatus ultimately saves some area for the printed circuit board, and attenuates switching noises between the power source layer and the ground layer of the high-frequency printed circuit board.

In accordance with the claimed invention, a leadframe packaging apparatus including a die, at least two separated die pads each connected to a corresponding voltage level, a plurality of leadfingers, and at least one passive component having two ends each connected to one of the two separated die pads, wherein the corresponding voltage levels are a power source voltage level and a ground voltage level. Each leadfinger has a first leadfinger section around the molding compound and a second leadfinger section extending to and within the molding compound, wherein the first and second leadfinger sections are connected with the printed circuit board underlying the molding compound and the die pads within the molding compound, thereby electrically connecting die pads with the printed circuit board. Passive components are not only placed on separated die pads but also bridge two different second leadfingers.

It is an advantage of the present invention that placing passive components within the molding compound of the leadframe packaging apparatus so as to save significant printed circuit board area and reduce switching noises between the power source layers and the ground layers. A packaging method relating to the leadframe packaging apparatus according to the present invention is further provided. This method has passive components placed upon die pads or bridged between two different second leadfinger sections before having the molding compound formed, so as to allow the molding compound to encase the die pads and passive components after the formation thereof.

These and other objects of the present invention will no doubt become obvious to those of ordinary skill in the art after reading the following detailed description of the preferred embodiment which is illustrated in the various figures and drawings.

### BRIEF DESCRIPTION OF THE DRAWINGS

FIG. 1 is a side view of a prior art leadfrme packaging apparatus connecting with a printed circuit board.

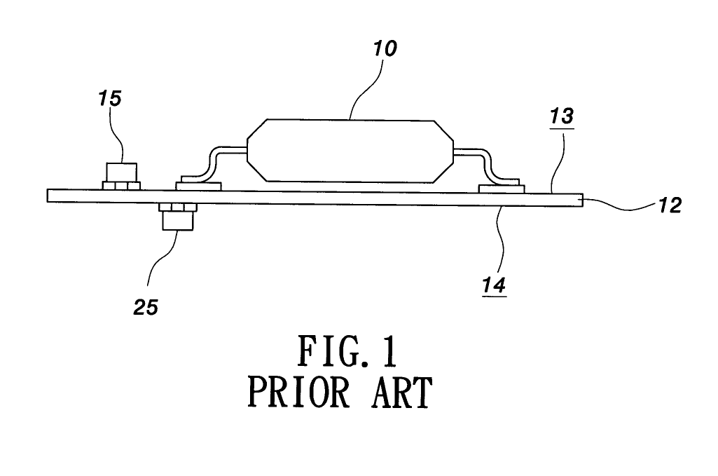

FIG. 2 is a cross sectional view of a present invention leadframe packaging apparatus.

FIG. 3 is a top view of the leadframe packaging apparatus according to the present invention.

FIG. 4A is a schematic diagram illustrating the position relationship between the power leadfingers and ground leadfingers.

FIG. 4B is an alternative embodiment also showing the position relationship ever disclosed in FIG. 4A.

FIG. 5 is a flow chart of packaging the present invention leadframe apparatus.

### DETAILED DESCRIPTION OF THE PREFERRED EMBODIMENT

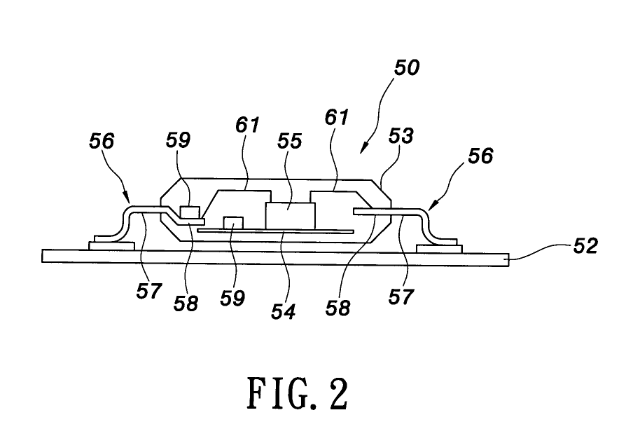

Please refer to FIG. 2 of a cross sectional view of a leadframe packaging apparatus 50 according to the present invention. The leadframe packaging apparatus 50 is placed upon and electrically connected with the printed circuit board 52. The apparatus 50 includes a molding compound 53 having a die pad 54 therein, an integrated circuit die 55 on the die pad 54, and a plurality of leadfingers 56 each having a first leadfinger section 57 outside and around the molding compound 53 and a second leadfinger section 58 extending to and within the molding compound 53. Passive components 59 are located on die pad 54 disposed in separated fashion or bridged between two distinct second leadfinger sections 59. The first leadfinger section 57 electrically couple to the printed circuit board 52 upholding the molding compound 53, and the integrated circuit die 55 connect with the second leadfinger section 58 through the metal wires 61, thereby to set up the electrical connection for the integrated circuit dies 55 and the printed circuit board 52.

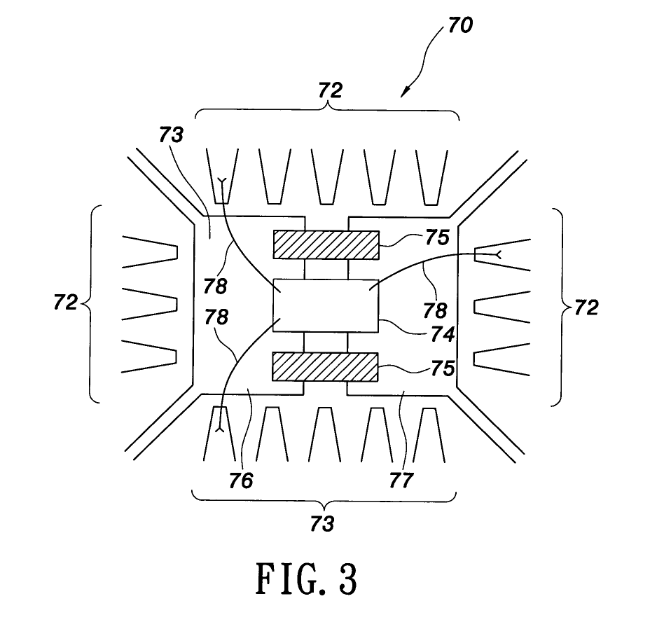

Please refer to FIG. 3 of a top view of the present invention leadframe packaging apparatus 70 having formed no molding compound. The leadframe packaging apparatus 70 includes a plurality of leadfingers 72, a separated die pad 73 within the molding compound, which has a die 74 and at least one passive component 75 thereon. The separated die pad 73 is divided into a power pad 76 and a ground pad 77, which are electrically connected with the printed circuit board supplying a power voltage level and a ground voltage level by leadfingers 72. In other words, leadfingers 72 are divided into a power leadfinger group, a ground leadfinger group, and a signal leadfinger group, all of which are not specified in this drawing. The power leadfinger group and the ground leadfinger group are connected to the power source voltage level and the ground voltage level, both of which are supplied by the printed circuit board, respectively. Passive components 75 and the integrated circuit die 74 are bridged between the power area 76 and the ground area 77. The die 74 further has other pins connected with the power leadfinger group, ground leadfinger group, and the signal leadfinger group through corresponding metal wires 78. It is noted that the power area 76 and the ground area 77 are maintained at the same plane, for the sake of facilitating the bridging between the die 74 and the passive component 75.

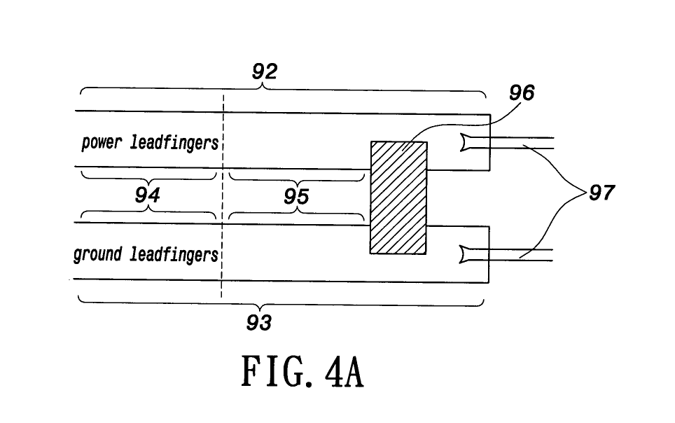

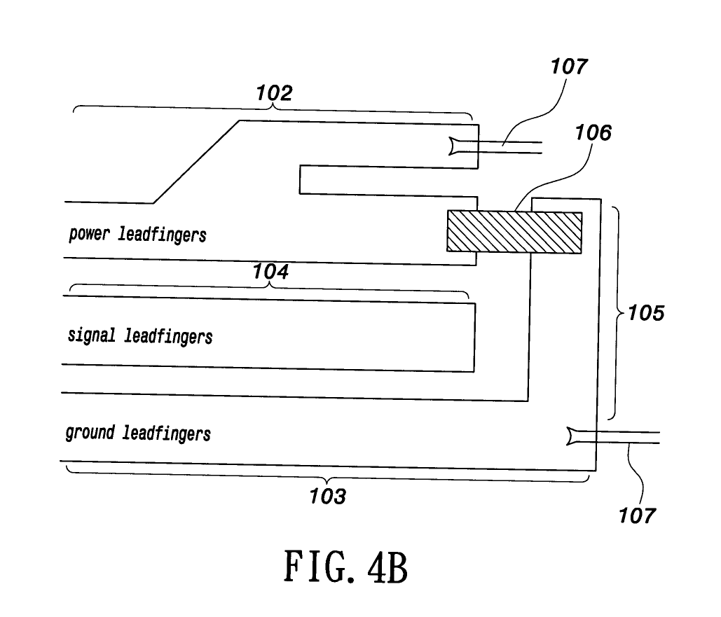

Please refer to FIG. 4A to FIG. 4B. FIG. 4A to FIG. 4B are schematic diagrams of illustrating how the passive component bridges two leadfingers according to an alternative embodiment FIG. 4A includes two kinds of leadfingers, which are power leadfingers 92 and ground leadfingers 93. The power leadfingers 92 and ground leadfingers 93 each further includes a first leadfinger section 94 located outside and around the molding compound, and a second leadfinger section 95 located inside of the molding compound. The passive component 96 bridges two adjacent second leadfinger sections 95, and power leadfingers 92 and ground leadfingers 93 connect with the integrated circuit die within the molding compound by metal wires 97. Compared with FIG. 4A, whose power leadfingers 92 and ground leadfingers 93 are adjacent, the embodiment disclosed in FIG. 4B further has signal leadfingers 104 between the power leadfingers 102 and ground leadfingers 103. Consequently, this embodiment includes a busbar 105 for facilitating the passive component 106 to bridge the power leadfingers 102 and the ground leadfingers 103. The busbar 105 not only extends from the ground leadfinger 103, but also locates at anywhere so as to bridge two non-adjacent leadfingers. Still, both power and ground leadfingers 102 and 103 connect to integrated circuit die through metal wires 107. FIG. 4B is not as same as FIG. 4A, where specifically defines one leadfinger into the first and second leadfinger section, otherwise, leadfingers in FIG. 4B are regarded as a part of second leadfinger sections, resulting in the passive component 106 is within the molding compound. Additionally, the passive component further bridges two adjacent first leadfinger sections, locating outside of the molding compound equivalently.

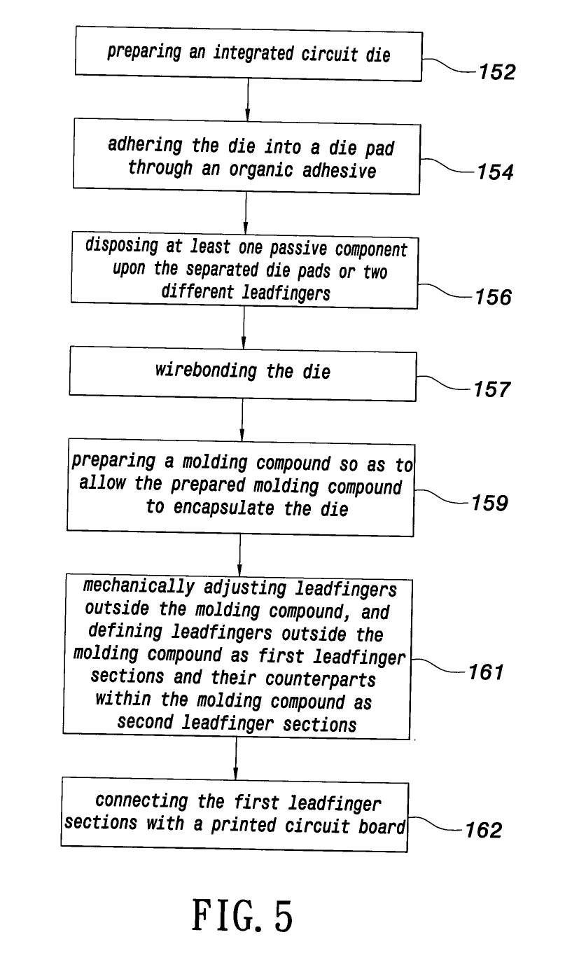

Please refer to FIG. 5 of a flow chart illustrating a method of packaging the leadframe packaging apparatus according to the present invention. The present invention method includes following steps:

Step 152: preparing an integrated circuit die, which is sliced from a wafer, and immersing the die into a de-ionized water to get rid of silicon dust and induced static charges during the slicing period;

Step 154: adhering the die into a die pad through an organic adhesive;

Step 156: disposing at least one passive component upon the separated die pads or two different leadfingers;

Step 157: wirebonding the die;

Step 159: preparing a molding compound so as to allow the prepared molding compound to encase the die, separated die pads, and the passive component;

Step 161: mechanically adjusting leadfingers outside the molding compound, and defining leadfingers outside the molding compound as first leadfinger sections and their counterparts within the molding compound as second leadfinger sections; and

Step 162: connecting the first leadfinger sections with a printed circuit board.

The most widely used materials in packaging the leadframe apparatus include the plastic-based plate and the metal leadframe, setting forth to reduce the thermal stress. The present invention is directed to the leadframe packaging apparatus having the molding compound thereof made of epoxy or ceramic. And at this point, no reference or prior art ever places the passive component into the molding compound before it is formed.

Selecting the epoxy as the molding compound material is just one preferred embodiment in this application. As a general rule, the selection of molding compound material depends on the size of the molding compound and the number of leadfingers. When we pick up epoxy as the molding compound material, the preferred adhesive for adhering the integrated circuit die into the die pad is the organic silver-filled epoxy.

Before adhering the integrated circuit die into the die pad, the bottom surface of the die requires to be metalized and the top surface of the die pad, opposing to the bottom surface of the die, proceeds with an electrically conductive adhesive in advance. The aforementioned metalization or proceeding with the electrically conductive adhesive is not for the sake of smoothing bottom surface of the die or top surface of the die pad, but having an ohmic contact between two said surfaces. On the heels of adhering, steps of placing passive components on separated die pads or two different leadfingers, and wirebonding the integrated circuit die are executed, as shown in steps 156 and 157, so as to assure passive components are within the molding compound. After the molding compound encases the die pads and passive components, leadfingers outside the molding compound are defined as first leadfinger sections and those inside of the molding compound are viewed as second leadfinegr sections. Passive components not only are placed on the separated die pads, but bridge two different second leadfinger sections. If two second leadfinger sections are not adjacent, a busbar extending from one of the two connecting-to-be second leadfinger sections is disposed so as to facilitate the bridging of passive components. The first and second leadfinger sections connect the printed circuit board and integrated circuit die, respectively. Furthermore, passive components are selectively to be placed between two adjacent first leadfinger sections. Regardless of the first or the second leadfinger sections, each of which is selected from the alloys. It is believed some other additional steps are included in the above packaging flow, such as the step of cleaning the excessive epoxy mechanically or chemically to proceed with remaining steps in the whole manufacturing procedure if the step of preparing the molding compound has induced too much epoxy.

In comparison with prior arts, the present invention provides a leadframe packaging apparatus having the passive component, such as a de-coupling capacitor, therein, and a method of packaging the apparatus. Placing the passive component upon the separated die pads or two adjacent/non-adjacent leadfingers, all of which are within the molding compound, not only releases the space of the printed circuit board supposed to place the passive component if the present invention is not provided, but attenuates the amplitude of high-frequency switching noises between the power source layer and the ground layer.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A leadframe packaging apparatus comprising:
a die;
at least two separated die pads each connected to a corresponding voltage level thereof;
a plurality of leadfingers; and
at least one passive component having two ends each connected to one of said two separated die pads.

2. The leadframe packaging apparatus of claim 1 wherein said voltage level is a power source voltage level and a ground voltage level.

3. The leadframe packaging apparatus of claim 2 wherein said power source voltage level and said ground voltage level is supplied by a printed circuit board, which is further fixedly connected with said leadframe packaging apparatus.

4. The leadframe packaging apparatus of claim 1 further comprising a busbar disposed between two non-adjacent leadfingers.

5. A leadframe packaging apparatus comprising:
a die;
a diepad;
a plurality of leadfingers; and
at least one passive component having two ends respectively connected to two leadfingers having two different voltage levels.

6. The leadframe packaging apparatus of claim 5 wherein the voltage levels comprises a power source voltage level and a ground voltage level.

7. The leadframe packaging apparatus of claim 6 wherein said power source voltage and said ground voltage level are supplied by a printed circuit board.

8. A packaging method for a leadframe packaging apparatus comprising steps as follows:
preparing an integrated circuit die;
adhering said integrated circuit die into a die pad;
preparing at least one passive component;
wirebonding said integrated circuit die;
preparing a molding compound for placing said integrated circuit die, said die pad, and said passive component therein;
defining said leadfingers outside of said molding compound as first leadfinger sections and said leadfingers inside of said molding compound as second leadfinger sections; and
electrically connecting said first leadfinger sections with a printed circuit board and said second leadfinger sections with said integrated circuit board.

9. The packaging method of claim 8 further comprising a step of having a busbar bridged two non-adjacent said second leadfinger sections.

10. The packaging method of claim 9, wherein said passive component further bridges one of two non-adjacent said second leadfinger sections and said busbar.

11. The packaging method of claim 8 wherein the passive component is further bridged between two adjacent said second leadfinger sections.

12. The packaging method of claim 8 further comprising a step of metalizing a bottom surface of said integrated circuit die before adhering said integrated circuit die into said die pad.

13. The packaging method of claim 8 wherein wirebonding said integrated circuit die is to wirebond a plurality of metal wires to said second leadfinger sections.

14. The packaging method of claim 8 wherein said leadfingers is made of an alloy.

15. The packaging method of claim 8 wherein said passive component further bridges two adjacent said first leadfinger sections.
